(19) United States
(12) Patent Application Publication
(10) Pub. No.: US 2011/0170569 A1
(43) Pub. Date: Jul. 14, 2011

(54) SEMIPOLAR III-NITRIDE LASER DIODES WITH ETCHED MIRRORS

(75) Inventors: Anurag Tyagi, Goleta, CA (US); Robert M. Farrell, Goleta, CA (US); Chia-Yen Huang, Goleta, CA (US); Po Shan Hsu, Arcadia, CA (US); Daniel A. Haeger, Goleta, CA (US); Kathryn M. Kelchner, Santa Barbara, CA (US); Hiroaki Ohta, Goleta, CA (US); Shuji Nakamura, Santa Barbara, CA (US); Steven P. DenBaars, Goleta, CA (US); James S. Speck, Goleta, CA (US)

(73) Assignee: THE REGENTS OF THE UNIVERSITY OF CALIFORNIA, Oakland, CA (US)

(21) Appl. No.: 12/908,478

(22) Filed: Oct. 20, 2010

Related U.S. Application Data
(60) Provisional application No. 61/258,235, filed on Nov. 5, 2009.

(51) Int. Cl. H01S 5/323; H01L 33/02; H01L 33/60; H01S 5/00; H01S 5/183

(52) U.S. Cl. 372/45.013; 438/46; 438/29; 372/44.01; 257/E33.023; 257/E33.068

(57) ABSTRACT

A semipolar {20-21} III-nitride based laser diode employing a cavity with one or more etched facet mirrors. The etched facet mirrors provide an ability to arbitrarily control the orientation and dimensions of the cavity or stripe of the laser diode, thereby enabling control of electrical and optical properties of the laser diode.

### CROSS REFERENCE TO RELATED APPLICATIONS

This application claims priority under 35 U.S.C. §119(e) to co-pending and commonly-assigned U.S. Provisional Patent Application Ser. No. 61/258,235, entitled “SEMIPOLAR {20-21} III-NITRIDE LASER DIODES WITH ETCHED MIRRORS,” filed on Nov. 5, 2009, by Anurag Tyagi, Robert M. Farrell, Chia-Yen Huang, Po Shan Hsu, Daniel A. Haeger, Kathryn M. Kelchner, Hiroaki Ohta, Shuji Nakamura, Steven P. DenBaars, and James S. Speck, attorney's docket number 30794.340-US-P1 (2010-275-1), which application is incorporated by reference herein.

### STATEMENT REGARDING FEDERALLY SPONSORED RESEARCH AND DEVELOPMENT

This invention was made with Government support under Grant No. FA8718-08-0005 awarded by DARPA-VIGIL. The Government has certain rights in this invention.

### BACKGROUND OF THE INVENTION

1. Field of the Invention

This invention relates to laser diodes (LDs), in particular, the development high-efficiency semipolar laser diodes emitting with etched facet mirrors operating, for example, in the green spectral range.

2. Description of the Related Art

(Note: This application references a number of different publications as indicated throughout the specification by one or more reference numbers within parentheses, e.g., (Ref. X). A list of these different publications ordered according to these reference numbers can be found below in the section entitled “References.” Each of these publications is incorporated by reference herein.)

Recently, green laser diodes (LDs) based on wurtzite (Al,In,Ga)N alloys have attracted significant attention as direct emission LD sources for next-generation display applications and as efficient replacements for solid state or gas lasers. Although second harmonic generation (SHG) green LDs are already available [Ref 1], III-nitride based green LDs offer the promise of reduced manufacturing costs, compactness, increased efficiency and reliability, and access to a wider range of available wavelengths.

Fueled by strong commercial interest, several groups are actively developing InGaN based green LDs on conventional polar c-plane wurtzite GaN. [Refs. 2-5] However, GaN-based heterostructures grown in the polar c-axis orientation have large fixed sheet charges that generate discontinuities in the spontaneous and strain-induced (piezoelectric) polarization, leading to large electric fields (˜1 MV/cm) in the quantum wells (QWs). [Ref 6] These large electric fields lead to a spatial separation of the electron and hole wavefunctions (quantum confined Stark effect (QCSE)), which results in a reduced radiative recombination rate and a large blue shift in the electroluminescence with increasing drive current, [Ref. 3] thus hindering expansion of lasing wavelength into the deep green spectral regime.

As an alternative, other groups have explored long wavelength LD structures grown on nonpolar m-plane [Refs. 7,8] and semipolar [Refs. 9-12] GaN orientations, to mitigate the deleterious effects of QCSE. Furthermore, a reduction in the valence band density of states and a resulting increase in optical gain are theoretically anticipated for semipolar and nonpolar InGaN/GaN multi-quantum well (MQW) structures due to unbalanced biaxial in-plane stress. [Ref 13]

The longest reported lasing wavelength for nonpolar m-plane LDs has been limited to 500 nm. [Ref. 8] Additionally, a high density of stacking faults (SFs) has been reported for m-plane QWs emitting around 560 nm. [Ref. 14]

In contrast, researchers from Sumitomo Electric Industries recently reported high quality green InGaN QWs grown on the novel (20-21) GaN crystal plane, enabling room-temperature (RT) electrically injected LD operation under pulsed (531 nm) and continuous wave (cw) (520 nm) conditions. Yoshizumi et al. employed lattice-matched quaternary AlInGaN cladding layers to provide sufficient transverse refractive index contrast to confine the optical mode. However, because of the large mismatch in ideal growth conditions (growth temperature, pressure, growth rate, etc.) between AlN/GaN and InN, it has previously been reported to be difficult to achieve high-quality quaternary AlInGaN epitaxial layers. [Refs. 15-18]

An expedient alternative to quaternary cladding layers is to use a large active region volume or high In-content InGaN waveguiding layers (with GaN cladding layers) to provide sufficient transverse modal confinement. [Refs. 19,20] The inventors have previously demonstrated cw operation of AlGaN-cladding free LDs in the violet [Ref 21] and pure blue [Ref 22] regions of the spectrum, demonstrating the viability of this design.

The present invention improves upon these developments by providing 506.4 nm RT lasing from AlGaN-cladding free LDs grown on semipolar (20-21) free-standing GaN substrates.

### SUMMARY OF THE INVENTION

To overcome the limitations in the prior art described above, and to overcome other limitations that will become apparent upon reading and understanding the present specification, the present invention describes techniques to fabricate semipolar III-nitride based heterostructure devices, such as laser diodes, employing semipolar {20-21} (Al,Ga,In)N substrates and InGaN/(Al,Ga,In)N based active regions. Moreover, the semipolar {20-21} III-nitride based laser diode of the present invention employs a cavity with one or more etched facet mirrors. The etched facet mirrors provide an ability to arbitrarily control the orientation and dimensions of the cavity or stripe of the laser diode, thereby enabling control of electrical and optical properties of the laser diode.

The invention present features both a novel structure and epitaxial growth method to improve structural, electrical and optical properties of such laser diodes, especially in the green spectral range.

### BRIEF DESCRIPTION OF THE DRAWINGS

Referring now to the drawings in which like reference numbers represent corresponding parts throughout:

FIG. 1 illustrates an embodiment of the present invention, namely an AlGaN-cladding-free semipolar (20-21) III-nitride based heterostructure device employing a cavity with one or more etched facet mirrors.

FIG. 2 is a scanning electron microscopy image of a test structure fabricated in accordance with the present invention showing a representative etched facet cross-section.

FIG. 3 is a scanning electron microscopy image of a test structure fabricated in accordance with the present invention showing a birds-eye view of representative etched facet surface morphology.

FIG. 4 is a flow chart showing the process steps for fabricating a semipolar {20-21} III-nitride based laser diode according to one embodiment of the present invention.

FIG. 5 is a graph of the corresponding refractive index profile and calculated optical mode intensity for the LD of FIG. 1, wherein the transverse confinement factor (G) was calculated to be 3.1%.

FIG. 6(a) is a graph of the pulsed light-current-voltage (L-I-V) characteristics of the 3×1500 μm² LD device measured before (solid lines) and after (dashed lines) application of high-reflectivity (HR) facet coatings.

FIG. 6(b) is graph of the pulsed lasing spectrum (504.2 nm) of the HR-coated LD, wherein the inset is a photograph of the on-wafer device under operation, with a clear far field pattern (FFP).

FIG. 7 is a graph of the dependence of spontaneous emission EL peak wavelength (filled squares) and full-width at half maximum (FWHM) (filled circles) on current density, wherein the peak EL wavelength data (open squares) for a 500 nm c-plane LD (OSRAM) (1-10 kA/cm²) are also shown for comparison, and the inset shows a fluorescence microscope image of the as grown LD epitaxial wafer.

FIG. 8(a) is a graph of the pulsed L-I-V characteristics for the (20-21) green LD, wherein measurements were taken at stage temperatures ranging from 20 to 60° C. with a duty cycle of 0.01% to avoid self-heating effects.

FIG. 8(b) is a graph of the temperature dependence of threshold current (Ith) (filled squares) and lasing wavelength (filled circles) under pulsed operation, wherein a characteristic temperature (T0) value of ˜130 K was estimated by fitting.

FIG. 9 is a graph of the dependence of lasing wavelength on duty cycle under pulsed operation at a fixed drive current (1300 mA), wherein the lasing wavelength is red-shifted due to device self-heating for duty cycles greater than 1%, and the inset shows the lasing spectrum (506.4 nm) at a duty cycle of 7%.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses electrically driven InGaN based laser diodes (LDs), with a simple AlGaN-cladding-free epitaxial structure, grown on semipolar (20-21) GaN substrates. The devices employed In_{0.06}Ga_{0.94}N waveguiding layers to provide transverse optical mode confinement. A maximum lasing wavelength of 506.4 nm was observed under pulsed operation, which is the longest reported for AlGaN-cladding-free III-nitride LDs. The threshold current density (Jth) for index-guided LDs with uncoated etched facets was 23 kA/cm², and 19 kA/cm² after application of high-reflectivity (HR) coatings. A characteristic temperature (T0) value of ˜130 K and wavelength red-shift of ˜0.05 nm/K were confirmed.

Device Structure

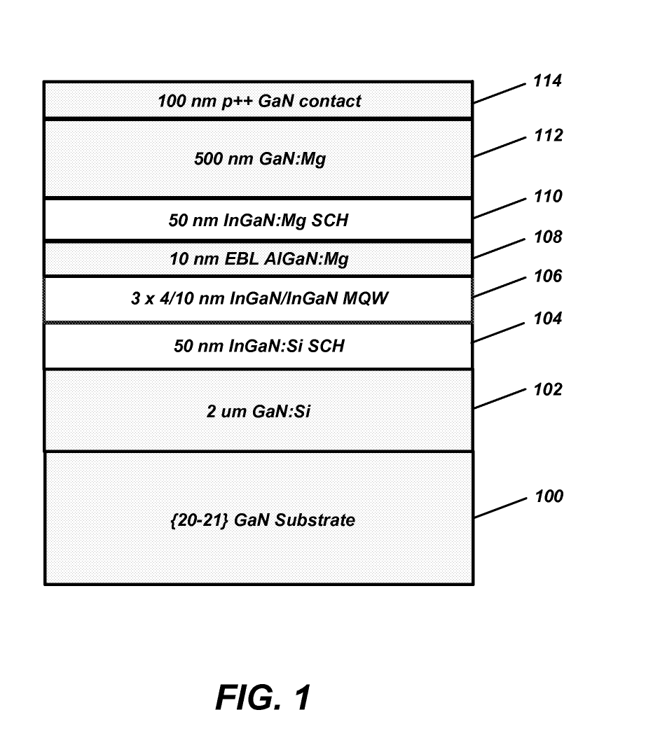

FIG. 1 illustrates an embodiment of the present invention, namely a semipolar {20-21} III-nitride based heterostructure device. Specifically, the device comprises a semipolar {20-21} III-nitride based laser diode grown on a semipolar {20-21} GaN substrate 100, and including a 2 μm GaN:Si cladding layer 102, a 50 nm In_{0.06}Ga_{0.94}N:Si separate confinement heterostructure (SCH) waveguiding layer 104, an active layer 106 comprising a 3 period multiple quantum well (MQW) stack with nominally 4 nm In_{0.3}Ga_{0.7}N quantum wells (QWs) and 10 nm In_{0.03}Ga_{0.97}N barriers, a 10 nm Al_{0.2}Ga_{0.8}N:Mg electron blocking layer (EBL) 108, a 50 nm In_{0.06}Ga_{0.94}N:Mg separate confinement heterostructure (SCH) waveguiding layer 110, a 500 nm GaN:Mg cladding layer 112, and a 100 nm p⁺⁺-GaN contact 114.

The semipolar {20-21} III-nitride based laser diode may be configured as an edge-emitting laser diode. Alternatively, the semipolar {20-21} III-nitride based laser diode may have smooth etched sidewalls with a vertical cavity, e.g., a VCSEL. Finally, the semipolar {20-21} III-nitride based laser diode may have passive cavities and/or saturable absorbers.

Etched Facet Mirrors

The semipolar {20-21} III-nitride based laser diode of FIG. 1 preferably employs one or more etched facet mirrors. These etched facet mirrors provide the ability to arbitrarily control the orientation and dimensions of the cavity or stripe of the laser diode, thereby enabling control of the electrical and optical properties of the laser diode.

The semipolar {20-21} III-nitride based laser diode may employ optical feedback from the etched mirror facets. For example, the etched mirror facets may provide optical gain to the semipolar {20-21} III-nitride based laser diode.

Alternatively, the etched mirror facets may suppress optical feedback in the semipolar {20-21} III-nitride based heterostructure device. In such a configuration, the etched mirror facets may be angled, and avoid vertical profiles.

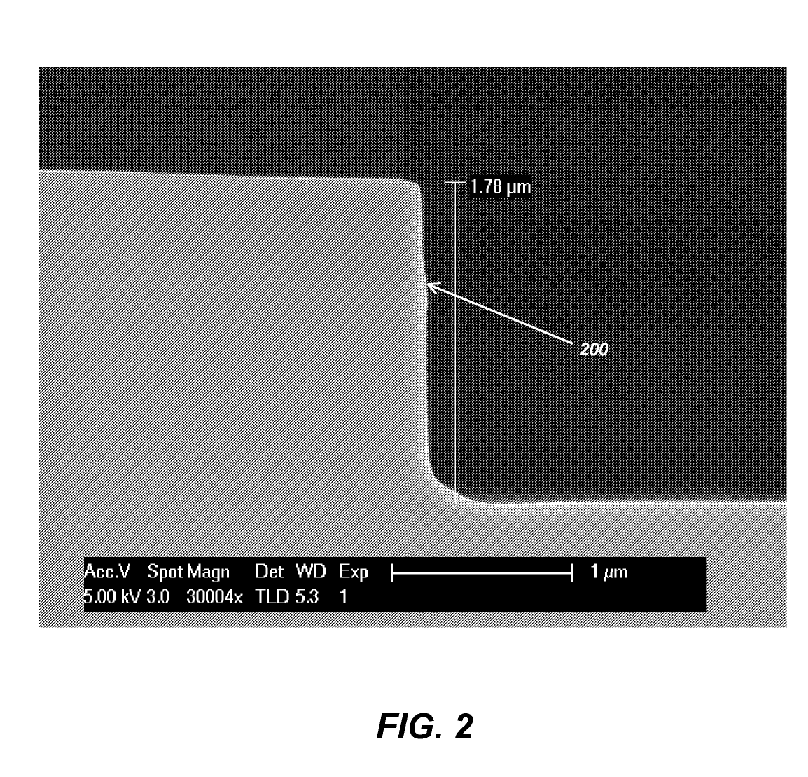

FIG. 2 is a scanning electron microscopy image of a test structure fabricated in accordance with the present invention showing a representative etched facet 200 cross-section. The facet 200 has a height of 1.78 μm and a nearly vertical profile.

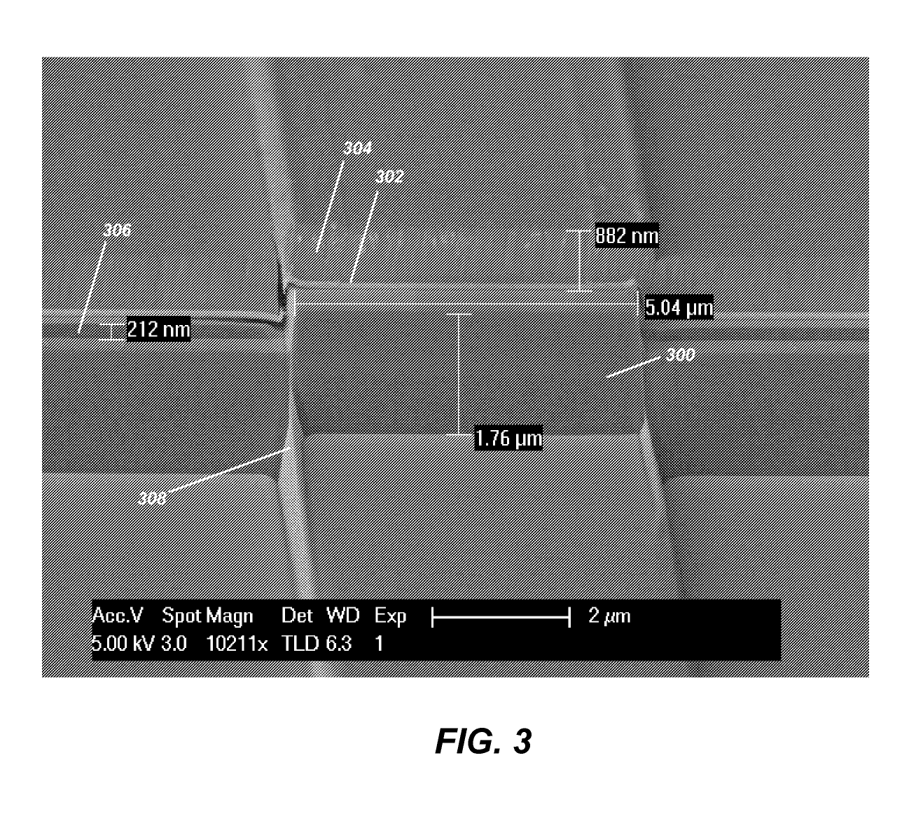

FIG. 3 is also a scanning electron microscopy image of a test structure fabricated in accordance with the present invention showing a birds-eye view of representative etched facet 300 surface morphology. The facet 300 has a height of 1.76 μm and a width of 5.04 μm, and is shown to be an extremely flat and smooth etched facet 300. FIG. 3 also shows a Pd contact 302 and an Au pad 304 having a combined height of 882 nm, and an SiO₂ insulator 306 having a height of 212 nm. Reference number 308 shows incompletely etched SiO₂ on the ridge sidewall.

Device Fabrication

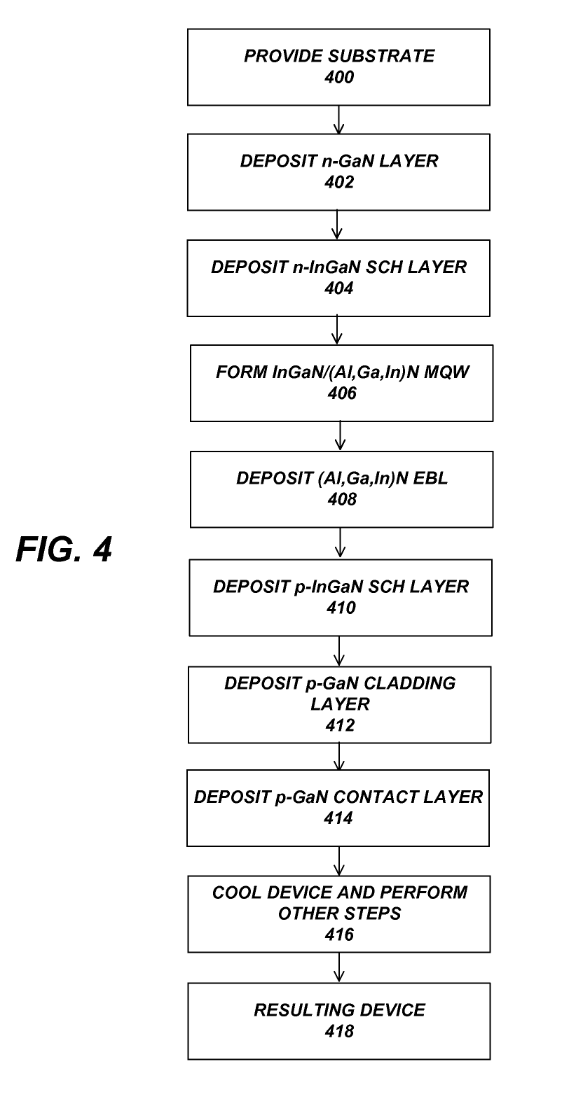

FIG. 4 is a flow chart showing the process steps for fabricating a semipolar {20-21}III-nitride based laser diode according to one embodiment of the present invention. Specifically, these steps may be used to fabricate the (Al,Ga,In)N epitaxial structures forming the laser diode as shown in FIG. 1 on a {20-21} III-nitride substrate using photolithography, metal and insulator deposition, formation of etched mirrors, etc.

The method may comprise the following steps.

Block 400 represents providing a semipolar {20-21} III-nitride substrate.

Block 402 represents depositing a 2 μm GaN:Si cladding layer epitaxially on the surface of the semipolar {20-21} III-nitride substrate.

Block 404 represents depositing a 50 nm In_{0.06}Ga_{0.94}N:Si separate confinement heterostructure (SCH) waveguiding layer epitaxially on the 2 μm GaN:Si cladding layer.

Block 406 represents forming an active layer comprising an InGan/(Al,Ga,In)N MQW structure epitaxially on the 50 nm In_{0.06}Ga_{0.94}N:Si SCH waveguiding layer. The InGan/(Al,Ga,In)N MQW structure typically comprises a plurality of quantum well layers sandwiched between barrier layers, which in this embodiment is a 3 period MQW stack with nominally 4 nm In_{0.3}Ga_{0.7}N quantum wells and 10 nm In_{0.03}Ga_{0.97}N barriers. This Block may include repeated steps of depositing a barrier layer followed by a quantum well layer, with the final layer being a barrier layer.

Block 408 represents depositing a 10 nm Al_{0.2}Ga_{0.8}N:Mg electron blocking layer (EBL) epitaxially on the active region.

Block 410 represents depositing a 50 nm In_{0.06}Ga_{0.94}N:Mg SCH waveguiding layer epitaxially on the 10 nm Al_{0.2}Ga_{0.8}N:Mg EBL.

Block 412 represents depositing a 500 nm GaN:Mg cladding layer epitaxially on the 50 nm In_{0.06}Ga_{0.94}N:Mg SCH waveguiding layer.

Block 414 represents depositing a 100 nm p⁺⁺-GaN contact epitaxially on the 500 nm GaN:Mg cladding layer.

Block 416 represents, following the depositing of the 100 nm p⁺⁺-GaN contact, cooling the device structure, and/or performing other steps necessary in the fabrication of the device structure, such as facet coating, creating DBRs, deposition of protective layers, dicing, cleaving, etc.

Block 418 represents the end result of the method, a device such as a semipolar {20-21} III-nitride laser diode structure shown in FIG. 1.

Preferably, the semipolar {20-21} III-nitride laser diode structure emits light having peak intensity at a wavelength that is green light, i.e., about 490 nm or greater; preferably, about 500 nm or greater; more preferably, about 504 nm or greater; and most preferably, about 506 nm or greater.

In various alternatives, the device may comprise an edge-emitting laser, a superluminescent diode, an optical amplifier, a photonic crystal (PC) laser, or vertical cavity surface emitting laser (VCSEL).

Note that prior art laser diodes with cleaved facets are limited by cavity length dimensions, and crystallographic orientation, and therefore control of optical/electrical properties is limited. In contrast, the semipolar {20-21} III-nitride based laser diode of the present invention is not so limited. The present invention provides for arbitrary control of cavity (device) dimensions. The prior art, in contrast, which employs cleaving, is limited by crystallography and mechanical reasons to lengths, for example, greater than ˜400 microns, such that good cleaved mirrors can only be formed if the cavity is aligned along certain crystallographic orientations.

In addition, the present invention enables the designer to place devices of varying dimensions adjacent on a small portion of wafer, thereby allowing for easier extraction of internal parameters for lasers, e.g., modal gain, loss, efficiency, etc. Moreover, the present invention minimizes facet variability, thereby enabling direct comparison of different cavity orientations.

Finally, the present invention also provides for an easier and quicker feedback mechanism for epitaxial characterization, because only lithography, deposition and etching involved.

Experimental Results

In experiments performed by the inventors, semipolar (20-21) LDs were grown by atmospheric pressure metal organic chemical vapor deposition (AP-MOCVD) on (20-21) oriented free-standing GaN substrates provided by the Mitsubishi Chemical Corporation. This simplified AlGaN-cladding-free structure helps avoid AlGaN-related cracking issues and also leads to significantly reduced growth times for LD epitaxial wafers. The as-grown epitaxial wafer was characterized by RT photoluminescence (PL) and fluorescence microscopy (FLM). The LD epitaxial wafer was processed as ridge waveguide LDs with stripes of varying widths formed by conventional lithographic patterning and dry etching ridges along the in-plane projection of the c-axis. A standard liftoff process was used for the oxide insulator, followed by Pd/Au metal deposition for the −p-electrode. The laser mirror facets were formed by dry etching and backside Al/Au contacts were used for the n-electrode. All measurements reported in this work were made on a 3×1500 μm² device.

Following the completion of the fabrication, the electrical and luminescence characteristics of the unpackaged and uncoated laser diodes were measured by on-wafer probing of the devices under pulsed operation to minimize self-heating effects. Unless specified otherwise, a pulse width of 100 ns and a repetition rate of 1 kHz (resulting in a duty cycle of 0.01%) were used for measurements throughout this article. Spontaneous emission spectra, below threshold, were collected through an optical fiber connected to an OceanOptics USB 2000+ array spectrometer (spectral resolution 1 nm). All lasing spectra were collected by coupling the output light from a single LD facet into a multi-mode fiber routed into an Ando AQ-6315A optical spectrum analyzer (OSA) with a resolution of 0.05 nm. After testing uncoated LDs, HR facet coatings were applied on both front and rear facets using a Veeco Nexus ion beam deposition (IBD) system using SiO₂ and Ta₂O₅ DBRs. The estimated power reflectivity for the front and rear HR coatings were 80 and 97%, respectively. The LDs were retested following the application of the HR coatings.

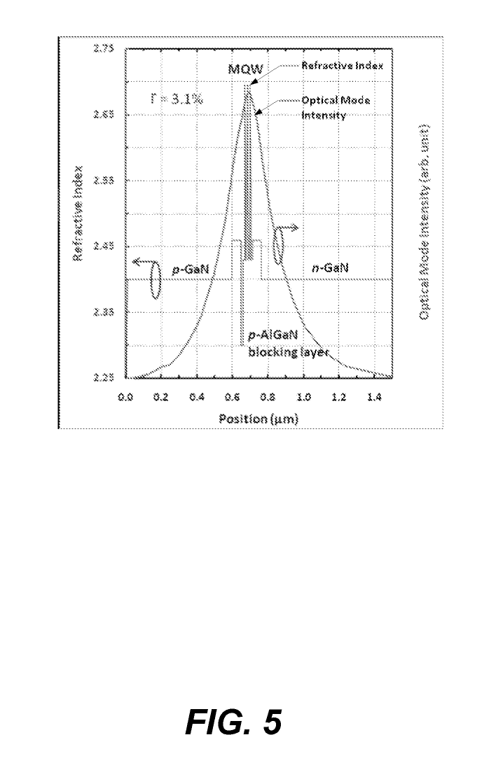

A refractive index profile (for a wavelength of 520 nm) and calculated optical mode intensity, using commercially available TCAD software (Synopsys), for the LD epitaxial structure of FIG. 1, is shown in FIG. 5. A transverse confinement factor (F) of approximately 3.1% is estimated for the structure. Further details of the modeling are provided elsewhere. [Ref. 20]

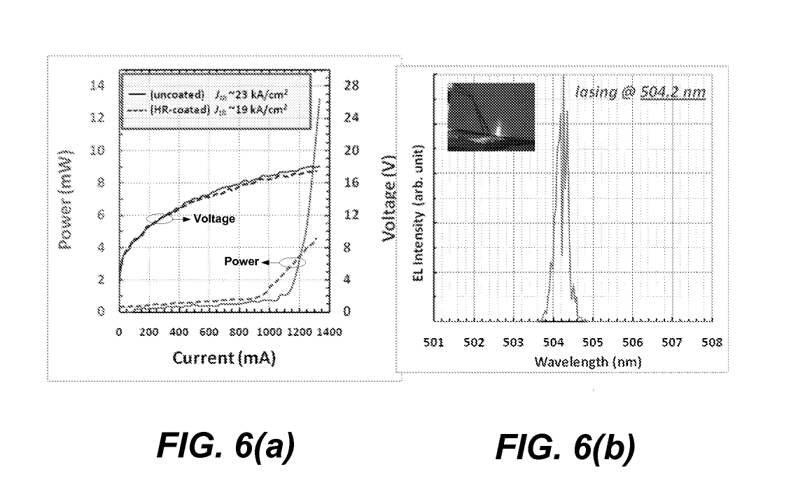

FIG. 6(a) is a graph of the pulsed light-current-voltage (L-I-V) characteristics of the 3×1500 μm² LD device measured before (solid lines) and after (dashed lines) application of HR facet coatings. The estimated threshold current (Ith) was approximately 1125 and 850 mA, corresponding to threshold current densities (Jth) of approximately 23 and 19 kA/cm², respectively. As expected, reduced mirror losses lead to a reduced Jth and a concomitant decrease in slope efficiency. [Ref 23] Threshold voltage (Vth) before and after HR-coating the facets was approximately 17.5 and 16 V, respectively. The relatively high threshold current and voltage are attributable to the un-optimized epitaxial structure and doping profile.

FIG. 6(b) shows the lasing spectrum of the HR-coated LD, wherein a lasing peak at 504.2 nm was observed. All pulsed measurements were performed at 0.01% duty cycle at RT. The inset shows a photograph of the on-wafer device under operation, with a clear far-field pattern (FFP).

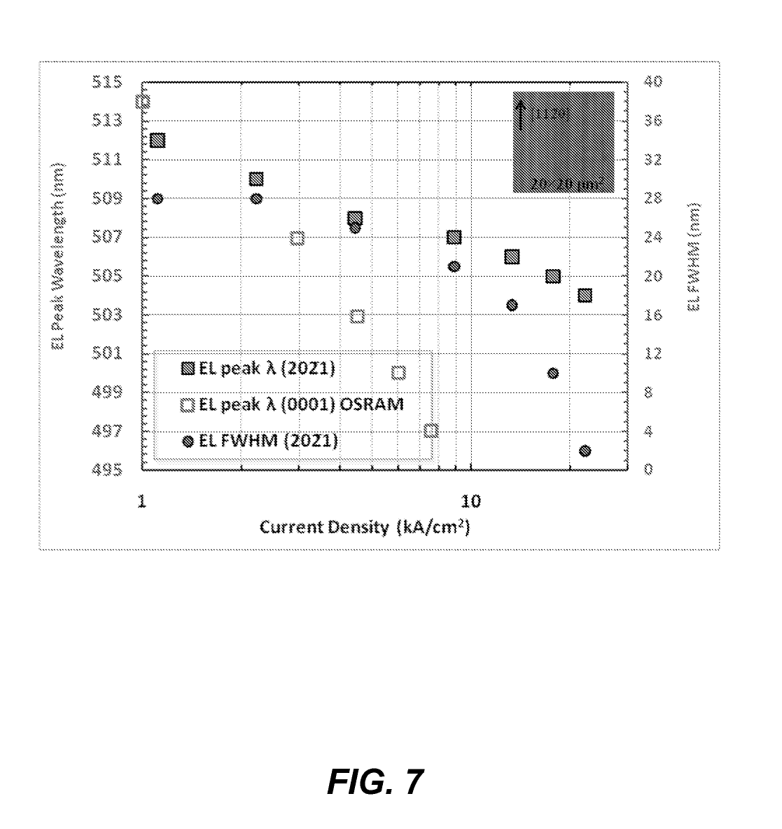

FIG. 7 is a graph of the dependence of spontaneous emission EL peak wavelength (filled squares) and full-width at half maximum (FWHM) (filled circles) on current density, wherein the peak EL wavelength data (open squares) for a 500 nm c-plane LD [Ref 3] (OSRAM) (1-10 kA/cm²) are also shown for comparison. It is noted that, in the 1-10 kA/cm² current density range, the blue-shift for the semipolar (20-21) LD device was much smaller than that for the c-plane LD, likely because of significantly reduced QCSE. Although Jth for the semipolar LD was twice as high, the lasing wavelength was longer than the c-plane LD, indicating even longer lasing wavelengths can be achieved by reducing the relatively high Jth. The FWHM values at low current density (<1 kA/cm²) (data not shown) compare favorably to previously reported values [Ref. 11] for green-emitting (20-21) QWs.

The inset in FIG. 7 shows a fluorescence microscope image of the as-grown LD epitaxial wafer. Few dark spots (indicative of non-radiative recombination regions) were observed, indicating good epitaxial quality of the MQW.

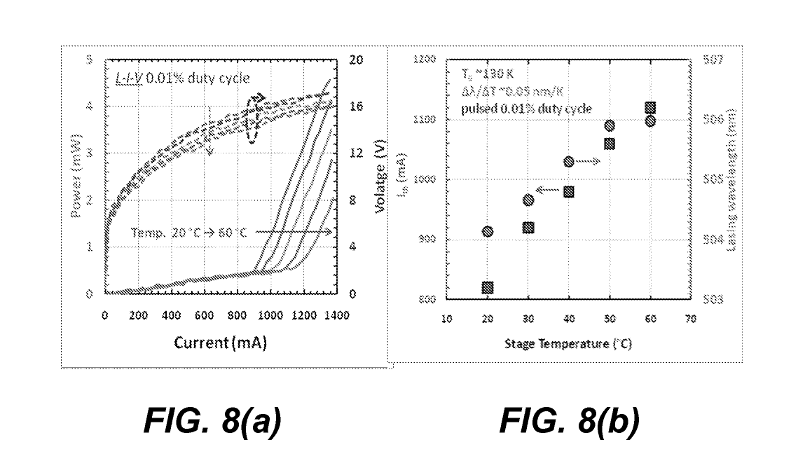

FIG. 8(a) is a graph of the pulsed L-I-V characteristics for the (20-21) green HR-coated LD as a function of stage temperature, wherein measurements were taken at stage temperatures ranging from 20 to 60° C. with a duty cycle of 0.01% to avoid self-heating effects. The measurements were made under pulsed operation (0.01% duty cycle) to minimize self-heating effects. As expected, due to broadened gain spectra and increased carrier escape out of QWs, Ith increases with increasing temperature.

FIG. 8(b) is a graph of the temperature dependence of threshold current (Ith) (filled squares) and lasing wavelength (filled circles) on the stage temperature under pulsed operation. A characteristic temperature (T0) value of approximately 130 K was estimated by fitting ln(Ith) with respect to absolute temperature. The T0 value is reasonable compared to reported values of 90 K (m-plane) [Ref. 8] and 120-200 K for c-plane green LDs. [Refs. 3-5] The lasing wavelength also red-shifted (0.05 nm/K) with increasing temperature due to thermally-induced reduction of the bandgap. Temperature dependent lasing wavelength shift of about 0.056 nm/K (m-plane) [Ref. 8] and 0.022-0.04 nm/K (c-plane) [Refs. 3-5] have previously been reported for green LDs. Lasing was observed up to 60° C. with a maximum lasing wavelength of 506 nm.

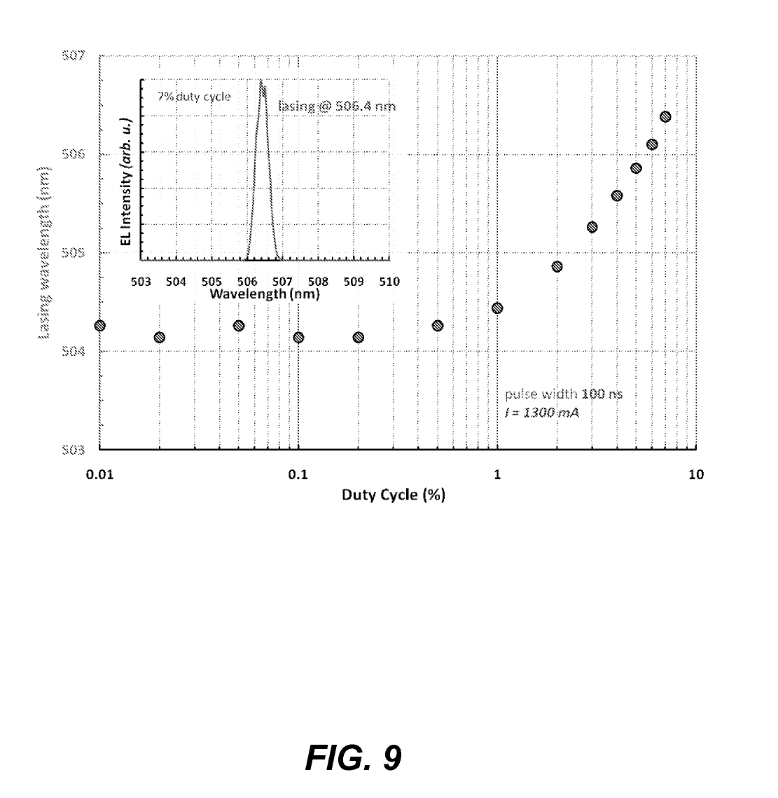

FIG. 9 shows the lasing wavelength, at a fixed current of 1300 mA, as a function of duty cycle under pulsed operation. The pulse width was fixed at 100 ns and the repetition rate was varied from 1 to 700 kHz to effectively vary the duty cycle. The lasing wavelength is red-shifted due to device self-heating for duty cycles greater than 1%. The lasing wavelength was stable below 0.5% duty cycle and thereafter red-shifted with increasing duty cycles, due to self-heating of the device. Lasing was observed up to 7% duty cycle with a maximum lasing wavelength of 506.4 nm (spectrum shown in inset).

In conclusion, semipolar (20-21) AlGaN cladding-free green LDs with InGaN waveguiding layers were demonstrated. A maximum lasing wavelength of 506.4 nm was achieved under pulsed operation. Spectral blue-shift until onset of lasing was significantly smaller than c-plane 500 nm LDs, underscoring the advantages of nonpolar/semipolar orientations for long-wavelength LDs.

Possible Modifications and Variations

There are a number of possible modifications and variations of the invention.

For example, substrate materials other than III-nitride substrates can be used in practicing this invention. Moreover, substrates with semipolar orientations other than {20-21} may be used. The substrate may also be thinned and/or polished in some instances.

Variations in the (Al,Ga,In)N quantum well and heterostructure design are possible without departing from the scope of the present invention. Various types of gain-guided and index guided laser diode structures can be fabricated. Moreover, the specific thickness and composition of the layers, the number of quantum wells grown, and the inclusion or omission of electron blocking layers are variables inherent to particular device designs and may be used in alternative embodiments of the present invention.

The described structure is an electrically-pumped device. An optically-pumped device can also be envisioned.

The layers, as depicted in FIG. 1, may be n-type, p-type, unintentionally doped (UID), co-doped, or semi-insulating, and may be composed of any (Al,Ga,In)N alloy, as well as other materials with desirable properties.

Different contact schemes, including, but not limited to, double lateral contacts, flip-chip and back-side contacts (n-contact to substrate, thus forming a vertical device structure) can be employed in alternative embodiments of the invention. Moreover, the contacts (both p-type and n-type contacts) may use different materials, e.g., Pd, Ag, Cu, ZnO, etc.

The etched facet mirrors described above maybe used for other semiconductor devices besides laser diodes, e.g., edge-emitting light emitting diodes (LEDs), superluminescent diodes, etc.

The facets may also be applied with different coatings to alter the reflectivity, e.g., high reflectivity (HR) or anti-reflective (AR) coatings, distributed Bragg reflector (DBR) mirrors, etc.

Advantages and Improvements

The purpose of the invention is for use as an optical source for various commercial, industrial, or scientific applications. For example, semipolar (Al,Ga,In)N edge-emitting laser diodes could provide an efficient, simple optical head for DVD players. Another application, which results from the shorter wavelength (for violet lasers) and smaller spot size provided by (Al,Ga,In)N semipolar lasers, is high resolution printing. Semipolar laser diodes offer the possibility of lower thresholds and it may even be possible to create laser diodes that emit in the longer wavelength regions of the visible spectrum (e.g., green (Al,Ga,In)N lasers). These devices would find applications in projection displays and medical imaging and are also strong candidates for efficient solid-state lighting, high brightness lighting displays, and may offer higher wall-plug efficiencies than can be achieved with LEDs.

Nomenclature

The terms (Al,Ga,In)N, III-nitride, Group III-nitride, nitride, Al_{(1-x-y)}GaₓIn_{y}N where 0≦x≦1 and 0≦y≦1, or AlInGaN, as used herein is intended to be broadly construed to include respective nitrides of the single species, Al, Ga and In, as well as binary, ternary and quaternary compositions of such Group III metal species. Accordingly, the term (Al,Ga,In)N comprehends the compounds AN, GaN, and InN, as well as the ternary compounds AlGaN, GaInN, and AlInN, and the quaternary compound AlGaInN, as species included in such nomenclature. When two or more of the (Al,Ga,In) component species are present, all possible compositions, including stoichiometric proportions as well as “off-stoichiometric” proportions (with respect to the relative mole fractions present of each of the (Al,Ga,In) component species that are present in the composition), can be employed within the broad scope of the invention. Accordingly, it will be appreciated that the discussion of the invention hereinafter in reference to specific (Al,Ga,In)N materials is applicable to the formation of various other species of these (Al,Ga,In)N materials. Further, (Al,Ga,In)N materials within the scope of the invention may further include minor quantities of dopants and/or other impurity or inclusional materials.

This invention also covers the selection of particular crystal terminations and polarities. The use of braces, { }, throughout this specification denotes a family of symmetry-equivalent planes. Thus, the {20-21} family includes the (20-21) plane and all symmetry-equivalent planes thereof. These symmetry-equivalent planes includes a wide variety of planes that possess two nonzero h, i, or k Miller indices, and a nonzero 1 Miller index. All planes within a single crystallographic family are equivalent for the purposes of this invention, although the polarity can affect the behavior of the growth process.

For example, (Al,Ga,In)N laser diodes in the past have typically grown on c-plane sapphire substrates, SiC substrates or bulk III-nitride substrates. In each instance, the laser diodes are usually grown along the polar (0001) c-axis orientation. Laser diodes grown on sapphire substrates usually employ dry-etched facets, which lead to higher losses and consequently to reduced efficiency, while laser diodes grown on SiC or bulk III-nitride substrates generally have cleaved mirror facets.

However, as noted above, conventional c-plane quantum well structures in III-nitride based optoelectronic and electronic devices suffer from undesirable QCSE, due to the existence of strong piezoelectric and spontaneous polarizations. Specifically, the strong built-in electric fields along the c-axis direction cause spatial separation of electrons and holes that, in turn, gives rise to restricted carrier recombination efficiency, reduced oscillator strength, and red-shifted emission.

One approach to eliminating the spontaneous and piezoelectric polarization effects in (Al,Ga,In)N optoelectronic devices is to grow the devices on nonpolar planes of the crystal. For example, with regard to GaN, such planes contain equal numbers of Ga and N atoms, and are charge-neutral. Furthermore, subsequent nonpolar layers are crystallographically equivalent to one another, so the crystal will not be polarized along the growth direction. Two such families of symmetry-equivalent nonpolar planes in GaN are the {11-20} family, known collectively as a-planes, and the {1-100} family, known collectively as m-planes.

Another approach to reducing or possibly eliminating the polarization effects in GaN optoelectronic devices is to grow the devices on semipolar planes of the crystal. As noted above, the term semipolar planes can be used to refer to a wide variety of planes that possess two nonzero h, i, or k Miller indices, and a nonzero 1 Miller index. Some examples of semipolar planes in the würtzite crystal structure include, but are not limited to, {20-21}, {10-12}, and {10-14}. The nitride crystal's polarization vector lies neither within such planes or normal to such planes, but rather lies at some angle inclined relative to the plane's surface normal.

In addition to spontaneous polarization, the second form of polarization present in nitrides is piezoelectric polarization. This occurs when the material experiences a compressive or tensile strain, as can occur when (Al,Ga,In)N layers of dissimilar composition (and therefore different lattice constants) are grown in a nitride heterostructure. For example, a strained AlGaN layer on a GaN template will have in-plane tensile strain, and a strained InGaN layer on a GaN template will have in-plane compressive strain, both due to lattice matching to the GaN. Therefore, for an InGaN quantum well on GaN, the piezoelectric polarization will point in the opposite direction than that of the spontaneous polarization of the InGaN and GaN. For an AlGaN layer latticed matched to GaN, the piezoelectric polarization will point in the same direction as that of the spontaneous polarization of the AlGaN and GaN.

The advantage of laser diodes grown on various semipolar orientations is that they have lower polarization-induced electric fields as compared to those grown on the polar (0001) c-axis orientation. Theoretical studies indicate that strained InGaN/GaN multiple quantum wells (MQWs) grown on semipolar orientations are expected have significantly lower effective hole masses than strained c-plane InGaN quantum wells. This should lead to a reduction in the threshold of semipolar (Al,Ga,In)N laser diodes as compared to those fabricated on the polar (0001) c-axis orientation.

### REFERENCES

The following references are incorporated by reference herein:
[1] U. Steegmueller, M. Kuehnelt, H. Unold, T. Schwarz, M. Schmitt, K. Auen, R. Schulz, C. Walter, I. Pietzonka, S. Illek, H. Lindberg, A. Gomez-Iglesias, M. Furitsch, C. Lauer, U. Strauss, and Thomas Hoefer: Proc. SPIE 7198 (2009) 719807.
[2] D. S. Sizov, R. Bhat, J. Napierala, J. Xi, D. E. Allen, C. S. Gallinat, and C.-E. Zah: Opt. Lett. 34 (2009) 328.
[3] D. Queren, A. Avramescu, G. Brüderl, A. Breidenassel, M. Schillgalies, S. Lutgen, and U. Straub: Appl. Phys. Lett. 94 (2009) 081119.
[4] A. Avramescu, T. Lermer, J. Muller, S. Tautz, D. Queren, S. Lutgen, and Uwe Strauβ: Appl. Phys. Lett. 95 (2009) 071103.
[5] T. Miyoshi, S. Masui, T. Okada, T. Yanamoto, T. Kozaki, S. Nagahama, and T. Mukai: Appl. Phys. Express 2 (2009) 062201.
[6] J. S. Speck and S. F. Chichibu: Mater. Res. Bull. 34 (2009) 304.
[7] Y. D. Lin, M. T. Hardy, P. S. Hsu, K. M. Kelchner, C. Y. Huang, D. A. Haeger, R. M. Farrell, K. Fujito, A. Chakraborty, H. Ohta, J. S. Speck, S. P. DenBaars, and S. Nakamura: Appl. Phys. Express 2 (2009) 082102.
[8] K. Okamoto, J. Kashiwagi, T. Tanaka, and M. Kubota: Appl. Phys. Lett. 94 (2009) 071105.
[9] A. Tyagi, Y. D. Lin, D. A. Cohen, M. Saito, K. Fujito, J. S. Speck, S. P. DenBaars, and S. Nakamura: Appl. Phys. Express 1 (2008) 091103.
[10] D. S. Sizov, R. Bhat, J. Napierala, C. Gallinat, K. Song, and C.-E. Zah: Appl. Phys. Express 2 (2009) 071001.
[11] Y. Enya, Y. Yoshizumi, T. Kyono, K. Akita, M. Ueno, M. Adachi, T. Sumitomo, S. Tokuyama, T. Ikegami, K. Katayama, and T. Nakamura: Appl. Phys. Express 2 (2009) 082101.
[12] Y. Yoshizumi, M. Adachi, Y. Enya, T. Kyono, S. Tokuyama, T. Sumitomo, K. Akita, T. Ikegami, M. Ueno, K. Katayama, and T. Nakamura: Appl. Phys. Express 2 (2009) 092101.
[13] S.-H. Park: Jpn. J. Appl. Phys. 42 (2003) L170.
[14] A. M. Fischer, Z. Wu, K. Sun, Q. Wei, Y. Huang, R. Senda, D. Iida, M. Iwaya, H. Amano, and F. A. Ponce: Appl. Phys. Express 2 (2009) 041002.
[15] M. E. Aumer, S. F. LeBoeuf, F. G. McIntosh, and S. M. Bedair: Appl. Phys. Lett. 75 (1999) 3315.
[16] Y. Liu, T. Egawa, H. Ishikawa, and T. Jimbo: J. Cryst. Growth 259 (2003) 245.
[17] S. Zhou, M. F. Wu, S. D. Yao, J. P. Liu, and H. Yang: Thin Solid Films 515 (2006) 1429.
[18] T. Yu, Y. Pan, Z. Yang, K. Xu, and G. Zhang: J. Cryst. Growth 298 (2007) 211.
[19] K. M. Kelchner, Y. D. Lin, M. T. Hardy, C. Y. Huang, P. S. Hsu, R. M. Farrell, D. A. Haeger, H. C. Kuo, F. Wu, K. Fujito, D. A. Cohen, A. Chakraborty, H. Ohta, J. S. Speck, S. Nakamura, and S. P. DenBaars: Appl. Phys. Express 2 (2009) 071003.
[20] C.-Y. Huang, Y.-D. Lin, A. Tyagi, A. Chakraborty, H. Ohta, J. S. Speck, S. P. DenBaars, and S. Nakamura: to be published in J. Appl. Phys.
[21] R. M. Farrell, D. F. Feezell, M. C. Schmidt, D. A. Haeger, K. M. Kelchner, K. Iso, H. Yamada, M. saito, K. Fujito, D. A. Cohen, J. S. Speck, S. P. DenBaars, and S. Nakamura: Jpn. J. Appl. Phys. 46 (2007) L761.
[22] K. M. Kelchner, Y.-D. Lin, M. T. Hardy, P. S. Hsu, C.-Y. Huang, C. Holder, D. A. Haeger, R. M. Farrell, H. Ohta, J. S. Speck, S. Nakamura, and S. P. DenBaars: presented at ICNS-8, 8th Int. Conf. on Nitride Semiconductors, 2009.
[23] U. Straub, S. Briininghoff, M. Schillgalies, C. Vierheilig, N. Gmeinwieser, V. Kümmler, G. Brüderl, S. Lutgen, A. Avramescu, D. Queren, D. Dini, C. Eichler, A. Lell, and U. T. Schwarz: Proc. SPIE 6894 (2008) 689417.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a semipolar III-nitride based heterostructure device employing a cavity with one or more etched facets.

2. The device of claim 1, wherein the etched facets are etched facet mirrors.

3. The device of claim 2, wherein the etched facet mirrors provide an ability to arbitrarily control orientation and dimensions of a cavity or stripe of the laser diode, thereby enabling control of electrical and optical properties of the laser diode.

4. The device of claim 1, wherein the cavity comprises a passive cavity or saturable absorber.

5. The device of claim 1, wherein the device is a laser diode (LD).

6. The device of claim 5, wherein the laser diode is a semipolar {20-21} III-nitride based laser diode.

7. The device of claim 6, wherein the semipolar {20-21} III-nitride based laser diode structure emits light having peak intensity at a wavelength that is green light.

8. The device of claim 1, wherein the device is an (Al,In,Ga)N epitaxial structure grown on a {20-21} substrate,

9. The device of claim 1, wherein the device is an edge-emitting laser, a superluminescent diode (SLD), an optical amplifier, a photonic crystal (PC) laser, or vertical cavity surface emitting laser (VCSEL).

10. A method of fabricating the optoelectronic device of claim 1.

11. A method of fabricating an optoelectronic device, comprising:
fabricating a semipolar III-nitride based heterostructure device employing a cavity with one or more etched facets.

12. The method of claim 11, wherein the etched facets are etched facet mirrors.

13. The method of claim 12, wherein the etched facet mirrors provide an ability to arbitrarily control orientation and dimensions of a cavity or stripe of the laser diode, thereby enabling control of electrical and optical properties of the laser diode.

14. The method of claim 11, wherein the cavity comprises a passive cavity or saturable absorber.

15. The method of claim 11, wherein the device is a laser diode (LD).

16. The method of claim 15, wherein the laser diode is a semipolar {20-21} III-nitride based laser diode.

17. The method of claim 16, wherein the semipolar {20-21} III-nitride based laser diode structure emits light having peak intensity at a wavelength that is green light.

18. The method of claim 11, wherein the device is an (Al,In,Ga)N epitaxial structure grown on a {20-21} substrate,

19. The method of claim 11, wherein the device is an edge-emitting laser, a superluminescent diode (SLD), an optical amplifier, a photonic crystal (PC) laser, or vertical cavity surface emitting laser (VCSEL).
